(19) United States
(12) Patent Application Publication
(10) Pub. No.: US 2013/0302520 A1
(43) Pub. Date: Nov. 14, 2013

(54) CO-EVAPORATION SYSTEM COMPRISING VAPOR PRE-MIXER

(71) Applicants: Kai-An Wang, Cupertino, CA (US); Michael Wong, Castro Valley, CA (US); Maosheng Ye, San Jose, CA (US); Albert Ting, San Jose, CA (US); Enhao Lin, Fremont, CA (US)

(72) Inventors: Kai-An Wang, Cupertino, CA (US); Michael Wong, Castro Valley, CA (US); Maosheng Ye, San Jose, CA (US); Albert Ting, San Jose, CA (US); Enhao Lin, Fremont, CA (US)

(21) Appl. No.: 13/540,517

(22) Filed: Jul. 2, 2012

Related U.S. Application Data
(60) Provisional application No. 61/645,770, filed on May 11, 2012.

(51) Int. Cl. C23C 16/455; C23C 16/52

(52) U.S. Cl. 427/255.23; 118/726; 118/724

(57) ABSTRACT

A processing system for depositing a plurality of source materials on a substrate, includes a first thermal evaporation source that can evaporate a first source material to produce a first vapor, a second thermal evaporation source that can evaporate a second source material to produce a second vapor, a vapor mixing chamber that allows the first vapor and the second vapor to be mixed to produce a mixed vapor, and conduits that can separately transport the first vapor and the second vapor to the vapor mixing chamber. The mixed vapor can be directed toward a substrate to deposit a mixture of the first source material and the second source material on the substrate. The processing system can also include vapor filters configured to regulate flows of the first vapor and the second vapor, and a mixed vapor filter to regulate flow of the mixed vapor.

The present application claims priority to pending U.S. Provisional Patent Application 61/645,770, entitled “Co-evaporation System Comprising Vapor Pre-mixer”, filed by the same inventors on May 11, 2012, the disclosures of which is incorporated herein by reference.

### BACKGROUND OF THE INVENTION

The present application relates to vacuum deposition technologies for depositing multiple materials.

In a conventional co-evaporation and co-deposition system 100, shown in FIG. 1, includes thermal evaporation sources 110, 120 for depositing materials to a substrate 130. The deposition sources 110, 120 include heaters 111, 121 respectively for heating source materials 112, 122. During evaporation, the heaters 111, 121 heat and vaporize the source materials 112, 122. The vapors are mixed in the vacuum and then condense on the substrate 130 to allow the two source materials to be deposited on the substrate 130. Some vapors condense on chamber walls (not shown) or other objects besides the substrate 130.

The strengths of the vapor fluxes from the thermal evaporation sources 110, 120 are not controlled. Thus the ratio of the source materials 112, 122 deposited on the substrate 130 is also not controlled. Moreover, the vapor flux decreases in strength as the portion of the substrate surface is further away from the thermal evaporation source 110 or 120; the deposition is non-uniform for each thermal evaporation source 110 or 120. In the example shown in FIG. 1, less source material 122 is deposited on the left side of the substrate 130 whereas less source material 112 is deposited on the right side of the substrate 130. Thus, the ratio of the deposited source materials 112, 122 is non-uniform on the substrate 130.

There is therefore a need to provide co-evaporation with accurate control on the mixture ratio of co-deposited materials with high deposition uniformity and minimum material waste.

### SUMMARY OF THE INVENTION

The present invention can overcome aforementioned deficiencies. The present application discloses flexible system and method for co-evaporation and co-deposition of multiple source materials. Vapor flows and thus ratio of the deposition materials are controlled by variable filters. The powers of the heating systems for different source materials are also controlled, which provide further control over the vapor fluxes. By using premixing vapor sources and tightly controlling vapor/mixture flows, the presently disclosed co-evaporation and co-deposition system can provide uniform deposition as well as uniform composition ratio over a large area substrate.

The vapor fluxes can be transported in an enclosed conduit to bring to close vicinity of the deposition surface on the substrate, which minimizes vapor leakage. The surfaces of the conduit are heated to prevent condensation of the vapor of the source material.

Moreover, the vapor fluxes can be directed in vertical, horizontal, and other directions according to the relative positions of the sources and the substrate, which provides flexibility the configurations and the foot prints of the deposition system.

Furthermore, the disclosed system uses replaceable parts to minimize source waste, and is thus economic to implement.

In one general aspect, the present invention relates to a processing system for depositing a plurality of source materials on a substrate. The processing system includes a first thermal evaporation source that can evaporate a first source material to produce a first vapor, a second thermal evaporation source that can evaporate a second source material to produce a second vapor, a vapor mixing chamber configured to allow the first vapor and the second vapor to be mixed to produce a mixed vapor, and conduits that can separately transport the first vapor and the second vapor to the vapor mixing chamber, wherein the mixed vapor is directed toward a substrate to deposit a mixture of the first source material and the second source material on the substrate.

Implementations of the system may include one or more of the following. The processing system can further include a temperature controller configured to control temperature of the vapor mixing chamber to optimize mixing of the first vapor and the second vapor. The first thermal evaporation source can include a first heater that can heat and evaporate the first source material. The second thermal evaporation source can include a second heater that can heat and evaporate the second source material. The processing system can further include a source evaporation controller configured to control the first heater and the second heater to control flow rates of the first vapor and the second vapor into the vapor mixing chamber. The processing system can further include a first vapor filter configured to regulate flow of the first vapor into the vapor mixing chamber and a second vapor filter configured to regulate flow of the second vapor into the vapor mixing chamber. The processing system can further include a mixed vapor filter configured to regulate flow of the mixed vapor out of the vapor mixing chamber. The processing system can further include one or more heaters configured to heat the conduits to prevent the first vapor and the second vapor from condensing on internal surfaces of the conduits. The processing system can further include a vent configured to direct the mixed vapor to a deposition surface of the substrate. The processing system can further include one or more heaters configured to heat the vent to prevent the mixed vapor from condensing on internal surfaces of the vent. The vapor mixing chamber is substantially above the substrate, and wherein the mixed vapor is directed downward to the substrate. The vapor mixing chamber can be substantially below the substrate, and wherein the mixed vapor is directed upward to the substrate.

In another general aspect, the present invention relates to a method for depositing a plurality of source materials on a substrate. The method includes evaporating a first source material to produce a first vapor; evaporating a second source material to produce a second vapor; transporting the first vapor and the second vapor in separate conduits to a vapor mixing chamber; allowing the first vapor and the second vapor to be mixed in the vapor mixing chamber to produce a mixed vapor; and directing the mixed vapor toward a substrate thereby depositing a mixture of the first source material and the second source material on the substrate.

Implementations of the system may include one or more of the following. The method can further include controlling temperature of the vapor mixing chamber to optimize mixing of the first vapor and the second vapor. The method can further include controlling temperature of the vapor mixing chamber to enable intermediary material formation or chemical reaction of the first vapor and the second vapor. The method can further include controlling evaporation rates of the first source material and the second source material by a source evaporation controller, thereby controlling flow rates of the first vapor and the second vapor into the vapor mixing chamber. The method can further include filtering the first vapor by a vapor filter before transporting the first vapor into the vapor mixing chamber. The vapor filter can include a plurality of holes configured to form a uniform flow of the first vapor into the vapor mixing chamber. The method can further include filtering the mixed vapor by a mixed vapor filter before directing the mixed vapor toward the substrate. The mixed vapor filter can include a plurality of holes configured to form a uniform flow of the mixed vapor toward the substrate. The method can further include heating the conduits to prevent the first vapor and the second vapor from condensing on internal surfaces of the conduits. The mixed vapor can be directed by a vent to the substrate. The method can further include heating the vent to prevent the mixed vapor from condensing on internal surfaces of the vent.

The details of one or more embodiments are set forth in the accompanying drawings and in the description below. Other features, objects, and advantages of the invention will become apparent from the description and drawings, and from the claims.

### BRIEF DESCRIPTION OF THE DRAWINGS

FIG. 1 shows a conventional co-evaporation and co-deposition system.

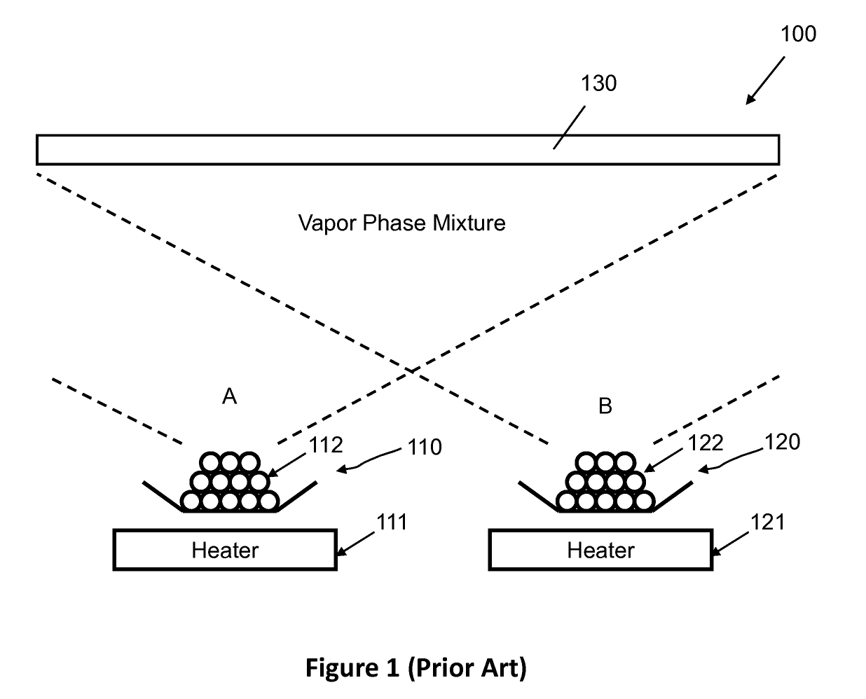

FIG. 2 shows a front view of a processing system for co-evaporation and co-deposition of multiple source materials in accordance with the present invention.

FIG. 3 shows a perspective view of a portion of the processing system in FIG. 2.

FIG. 4 shows detailed views of a vapor filter and a mixed vapor filter compatible with the processing system in FIG. 2.

FIG. 5 shows a perspective view of a processing system having vapor transport and mixing in an inverted position in accordance with the present invention.

FIG. 6 is a flowchart for co-evaporation and co-deposition of multiple source materials in accordance with the present invention.

### DETAILED DESCRIPTION OF THE INVENTION

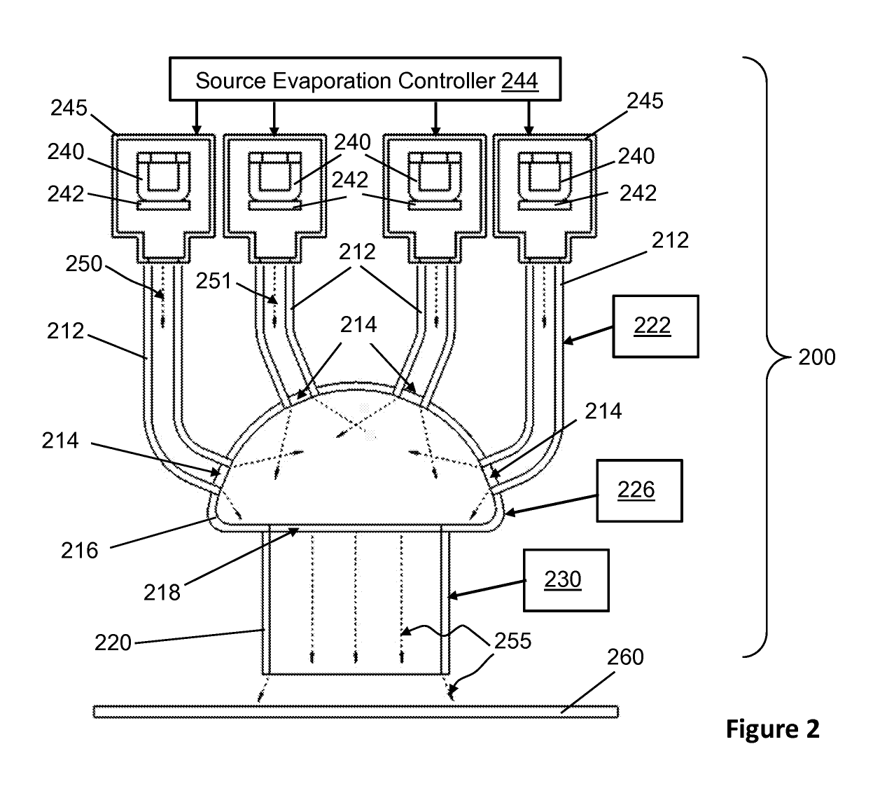

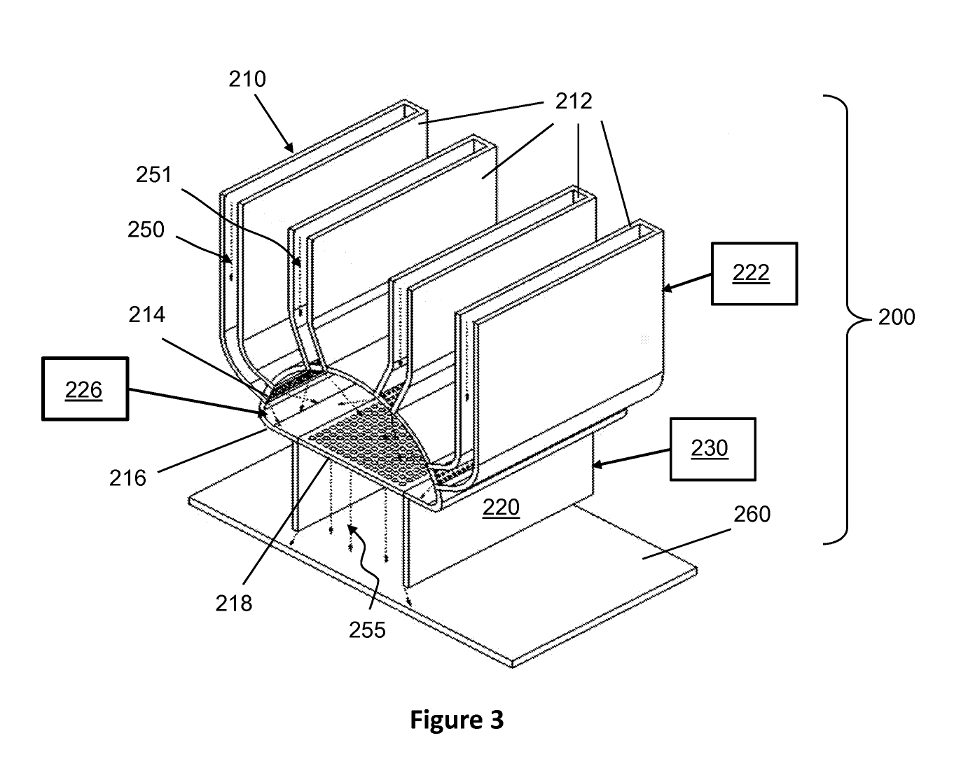

Referring to FIGS. 2-3, a processing system 200 for co-evaporation and co-deposition includes vapor channels 212 (i.e. vapor conduits) through which source vapors are introduced, vapor filters 214 at the end of the vapor channels 212, a vapor mix chamber 216 in fluidic communication with the vapor channels 212, a mixed vapor filter 218, and a vent 220 that directs fluxes of mixed vapor 255 toward a substrate 260. The processing system 200 can also include evaporation sources, chamber walls, vacuum pumping system, load-lock station, and substrate holder and transport system, which are not shown in FIGS. 2-3 and 5 for clarity reason.

The processing system 200 includes evaporation sources 240 that are enclosed in chambers 245. The chambers 245 are respectively connected to the vapor channels 212. The evaporation sources 240 each includes a separate heater 242 for heating and evaporating source materials. The heaters 242 in the different evaporation sources 240 are individually controlled by a source evaporation controller 244 which controls evaporation rates of the different source materials. The vapor channels 212 are configured to respectively receive fluxes of vapors 250, 251 produced by evaporation sources 240. The flux strengths of the vapors 250, 251 can thus be separately controlled to ensure proper balance between evaporations of different source materials and thus uniform material composition to be deposited on the substrate 260. During co-evaporation and co-deposition of different source materials, at least some of source materials at the evaporation sources 240 include different source materials.

The vapors 250, 251 flow through separate vapor channels 212 into the vapor mix chamber 216. The shapes and dimensions of the vapor channels 212 can vary with the position and geometry of the evaporation sources 240. The vapors 250, 251 are enclosed respectively by the different vapor channels 212 and then by the vapor mix chamber 216, which prevents leakage and material deposition on unwanted object such as chamber walls, and minimizes waste of the source materials. The walls of the vapor channels 212 are heated by a heating device 222 during the operation to prevent condensation of the vapors 250, 251 on the walls of the vapor channels 212.

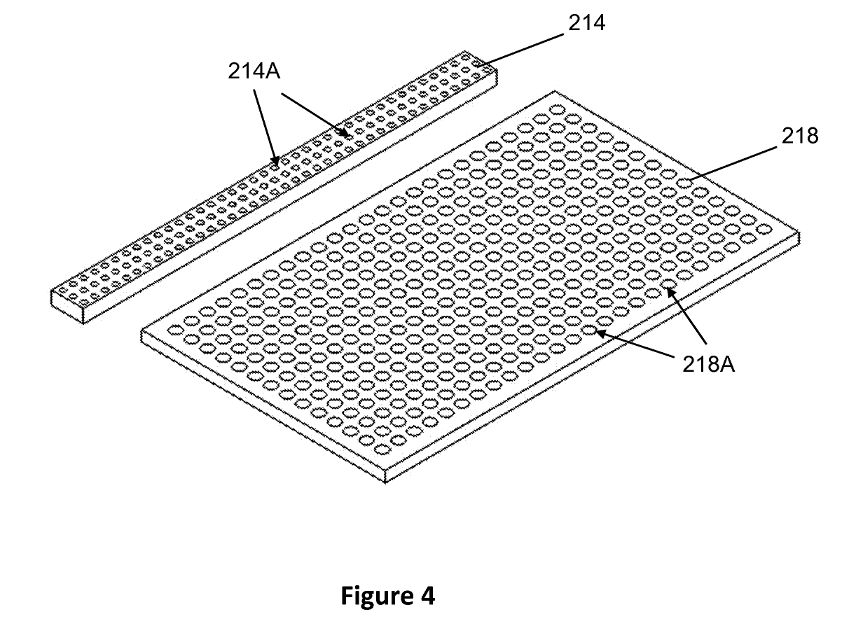

Densities of individual fluxes of the vapors 250, 251 can be controlled by the vapor filters 214 installed at the interfaces of the vapor channels 212 and the vapor mix chamber 216. The vapor filter 214, as shown in FIG. 4, includes a plurality of holes 214A to provide a uniform flow of a vapor 250 or 251 into the vapor mix chamber 216. The vapor filters 214 are changeable or replaceable, which provides flexibility and economy to the processing system 200.

The different vapors 250, 251 are mixed in the vapor mix chamber 216. The temperature of the vapor mix chamber 216 can be controllable by a mixing temperature controller 226 to optimize mixing of the vapors 250, 251 of different source materials. The mixing temperature can be an important process parameter. For example, a heated vapor mix chamber above certain temperature can promote the formation of certain intermediate material phases (collective merits of composition and structure) that may be needed to form the desired final phase on the substrate 260. In other words, the mixing temperature can be used to control reaction path to forming the desired phase on the substrate 260. In another example, under certain mixing temperature and certain pressure in the vapor mix chamber, chemical reactions of the source vapors can take place in the space before the vapors 250, 251 reaching the substrate 260. The chemical reactions can produce nano-sized particles. Under other mixing temperature and pressure conditions, the chemical reactions can take place at the surface of the substrate 260 to form thin films on the substrate 260. The mixed vapor 255 is output through a mixed vapor filter 218 to a vent 220. As shown in FIG. 4, the mixed vapor filter 218 includes a plurality of perforated holes 218A configured to form uniformly distributed fluxes of mixed vapor 255 through the vent 220 as well as to control flux density of the mixed vapor. The mixed vapor filter 218 is also a replaceable part. The vent 220 directs the mixed vapor 255 to the surface of the substrate 260.

The vent 220 surrounds the mixed vapor 255 and guides it toward the substrate 260. In deposition operation, the vent 220 is heated by a heating device 230 to be at higher temperature than that of the substrate 260 to prevent the mixed vapor 255 from condensing on the vent surfaces.

In some embodiments, the length of the vent 220 can be varied to adjust the clearance between the vent 220 and the substrate 260. For example, the vent 220 can be implemented by a flexible pipe. A small clearance ensures maximum deposition of the vapor mixture on the substrate 260 and minimized waste.

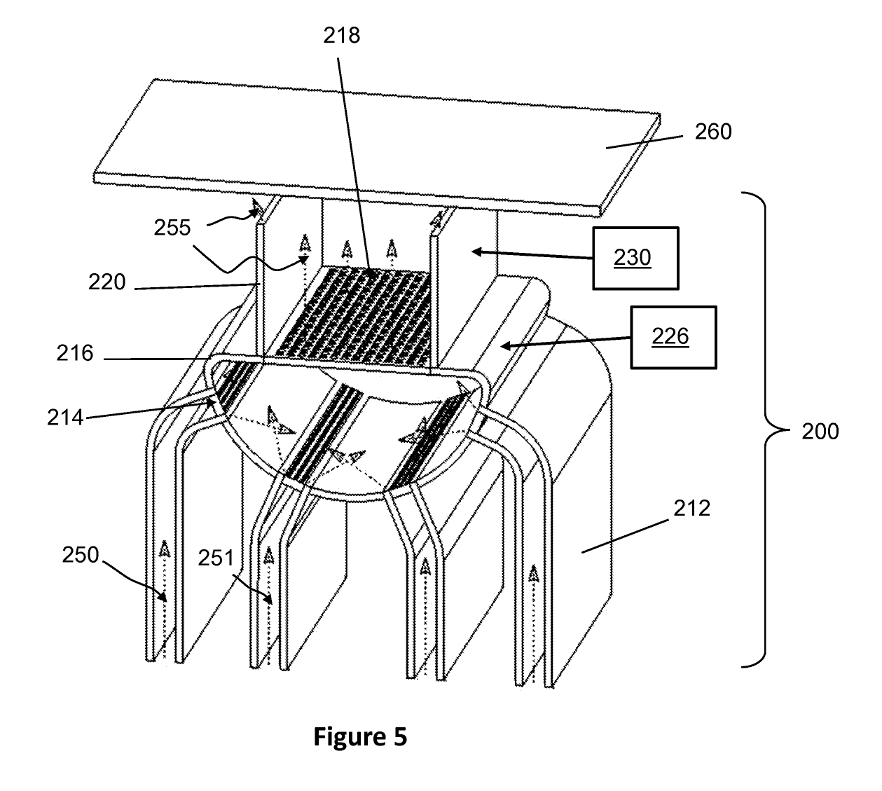

The disclosed processing system 200 can be positioned in different orientations according to the positions of the sources and the substrate. For example, as shown in FIG. 5, the processing system 200 is positioned in an inverted position to direct the mixed vapor 255 upward toward a lower surface of the substrate 260. For clarity, the evaporation sources 240, the heaters 242, and the source evaporation controller 244 are not shown in FIG. 5.

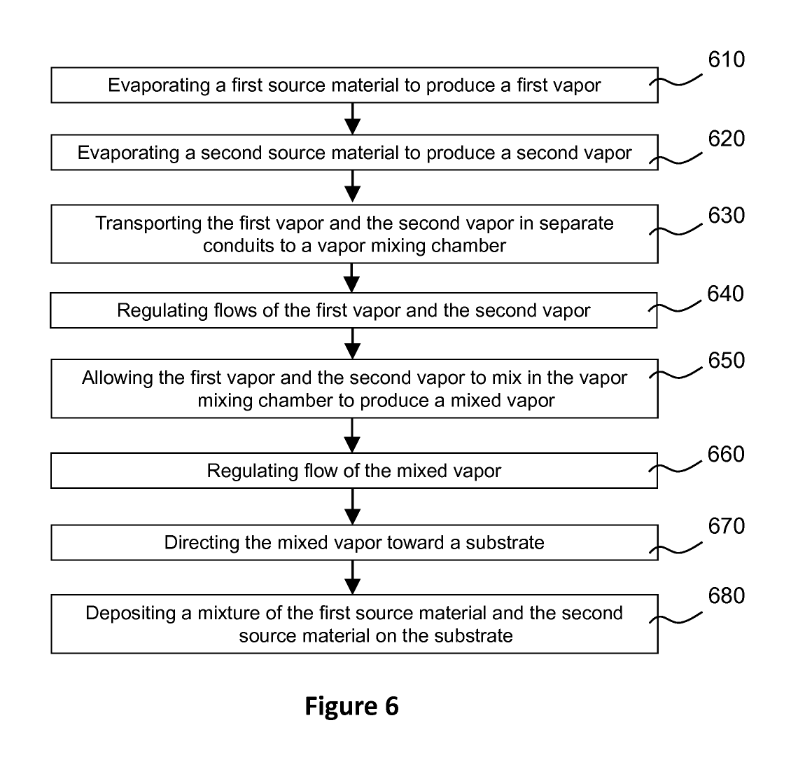

Referring to FIG. 6, the disclosed method for depositing a plurality of source materials on a substrate can include one or more of the following steps: a first source material is evaporated by a first thermal evaporation source to produce a first vapor (step 610). A second source material is evaporated by a second thermal evaporation source to produce a second vapor (step 620). The flux strengths of the vapors can be controlled by controlling evaporation rates of the different source materials. The first vapor and the second vapor are transported in separate conduits to a vapor mixing chamber (step 630). The first vapor and the second vapor can be separately regulated by filters to improve uniformity and flow intensities (step 640). The first vapor and the second vapor are mixed in the vapor mixing chamber to produce a mixed vapor (step 650). The mixed vapor is regulated by a filter to improve uniformity and flow intensities (step 660). The temperature of the vapor mixing can be controlled. The mixed vapor is directed toward a substrate by a vent (step 670). A mixture of the first source material and the second source material is deposited on the substrate (step 680).

It is understood that the disclosed systems are compatible with many different types of evaporation and deposition processes such as thermal evaporation, thermal sublimation, CVD (chemical vapor deposition), PECVD (plasma-enhanced chemical vapor deposition), etc. The disclosed processing systems can include other components such as load lock, transport mechanism for the substrates, vacuum pump systems, etc. without deviating from the spirit of the invention. The deposition materials can be provided by sputtering targets, gas distribution device, and other types of source units without deviating from the spirit of the invention. The disclosed processing system can have vapor flux transport and mixing oriented in other directions from the examples described above.

What is claimed is:

1. A processing system for depositing a plurality of source materials on a substrate, comprising:
a first thermal evaporation source configured to evaporate a first source material to produce a first vapor;
a second thermal evaporation source configured to evaporate a second source material to produce a second vapor;
a vapor mixing chamber configured to allow the first vapor and the second vapor to be mixed to produce a mixed vapor; and
conduits configured to separately transport the first vapor and the second vapor to the vapor mixing chamber, wherein the mixed vapor is directed toward a substrate to deposit a mixture of the first source material and the second source material on the substrate.

2. The processing system of claim 1, further comprising:
a temperature controller configured to control temperature of the vapor mixing chamber to optimize mixing of the first vapor and the second vapor.

3. The processing system of claim 1, wherein the first thermal evaporation source comprises a first heater configured to heat and evaporate the first source material, wherein the second thermal evaporation source comprises a second heater configured to heat and evaporate the second source material, the processing system further comprising:
a source evaporation controller configured to control the first heater and the second heater to control flow rates of the first vapor and the second vapor into the vapor mixing chamber.

4. The processing system of claim 1, further comprising:
a first vapor filter configured to regulate flow of the first vapor into the vapor mixing chamber; and
a second vapor filter configured to regulate flow of the second vapor into the vapor mixing chamber.

5. The processing system of claim 1, further comprising:
a mixed vapor filter configured to regulate flow of the mixed vapor out of the vapor mixing chamber.

6. The processing system of claim 1, further comprising:
one or more heaters configured to heat the conduits to prevent the first vapor and the second vapor from condensing on internal surfaces of the conduits.

7. The processing system of claim 1, further comprising:
a vent configured to direct the mixed vapor to a deposition surface of the substrate.

8. The processing system of claim 7, further comprising:
a heater configured to heat the vent to prevent the mixed vapor from condensing on internal surfaces of the vent.

9. The processing system of claim 1, wherein the vapor mixing chamber is substantially above the substrate, and wherein the mixed vapor is directed downward to the substrate.

10. The processing system of claim 1, wherein the vapor mixing chamber is substantially below the substrate, and wherein the mixed vapor is directed upward to the substrate.

11. A method for depositing a plurality of source materials on a substrate, comprising:
evaporating a first source material to produce a first vapor;
evaporating a second source material to produce a second vapor;
transporting the first vapor and the second vapor in separate conduits to a vapor mixing chamber;
allowing the first vapor and the second vapor to be mixed in the vapor mixing chamber to produce a mixed vapor; and
directing the mixed vapor toward a substrate thereby depositing a mixture of the first source material and the second source material on the substrate.

12. The method of claim 11, further comprising:
controlling temperature of the vapor mixing chamber to optimize mixing of the first vapor and the second vapor.

13. The method of claim 11, further comprising:
controlling temperature of the vapor mixing chamber to enable intermediary material formation or chemical reaction of the first vapor and the second vapor.

14. The method of claim 11, further comprising:
controlling evaporation rates of the first source material and the second source material by a source evaporation controller, thereby controlling flow rates of the first vapor and the second vapor into the vapor mixing chamber.

15. The method of claim 11, further comprising:
filtering the first vapor by a vapor filter before transporting the first vapor into the vapor mixing chamber.

16. The method of claim 15, wherein the vapor filter comprises a plurality of holes configured to form a uniform flow of the first vapor into the vapor mixing chamber.

17. The method of claim 11, further comprising:
filtering the mixed vapor by a mixed vapor filter before directing the mixed vapor toward the substrate.

18. The method of claim 17, wherein the mixed vapor filter comprises a plurality of holes configured to form a uniform flow of the mixed vapor toward the substrate.

19. The method of claim 11, further comprising:
heating the conduits to prevent the first vapor and the second vapor from condensing on internal surfaces of the conduits.

20. The method of claim 11, wherein the mixed vapor is directed by a vent to the substrate, the method further comprising:
heating the vent to prevent the mixed vapor from condensing on internal surfaces of the vent.
